(19) United States
(12) Patent Application Publication
(10) Pub. No.: US 2023/0169231 A1
(43) Pub. Date: Jun. 1, 2023

(54) COMPUTATIONAL MODELING, CLIMATE PLAN SCORING, AND DATA TAGGING

(71) Applicant: CLIMATEVIEW AB, Umeå (SE)

(72) Inventors: Tomer SHALIT, Umeå (SE); Mark DIXON, Umeå (SE); Jeff GOENS, Umeå (SE)

(21) Appl. No.: 17/920,729

(22) PCT Filed: May 18, 2021
(86) PCT No.: PCT/IB2021/000342

§ 371 Date: Oct. 21, 2022

Related U.S. Application Data
(60) Provisional application No. 63/145,010, filed on Feb. 3, 2021.
(60) Provisional application No. 63/083,175, filed on Sep. 25, 2020.
(60) Provisional application No. 63/026,767, filed on May 19, 2020.

(51) Int. Cl. G06F 30/20

(52) U.S. Cl. CPC G06F 30/20

(57) ABSTRACT

Processing systems analyze data structures that characterize plans for combating climate change. The plans are represented by data structures that characterize one or more transition targets, each including (or associated with) data characterizing the significance of the change, the likelihood it will take place, the confidence level in those estimates, and other information, and how those might change over time. The system traverses the data structure and produces one or more scores characterizing the plan. Some embodiments iterate over the initial plan data structure or a space derived from the initial plan data structure, moving toward a plan that meets overall goals, preferably while supporting a necessary level of activity. Agent-based modeling drives some embodiments to optimize outputs toward particular metrics and/or with particular constraints.

### FIELD

The disclosed technology pertains to the field of processing data by operating upon the order or content of the data handled, particularly, arrangements for selecting data on individual record carriers and processing records accordingly.

### BACKGROUND

Climate change is a grand-scale problem that requires a comprehensive, visualized, and shared approach. Although we have the knowledge, political will, and solutions in front of us, we have not managed to sufficiently accelerate carbon reduction as of today—in part due to a lack of mission-orientation. Accordingly, there is a need for technology that allows for, and supports, a mission-oriented approach to tackling climate change.

Further, the incredible amounts of information needed to fully model climate change—and the overwhelming proportion of that information that is unknown about the present or not yet even in existence make complete, long-term modeling of the climate utterly intractable. What is needed, therefore, is a system for operating on the order or content of data to facilitate scoring, tagging, and acting upon climate-related data and activities.

### BRIEF DESCRIPTION OF THE DRAWINGS

It is believed the disclosed technology may be understood in light the following description of certain examples taken in conjunction with the accompanying drawings, in which like reference numerals identify the same elements and in which:

FIG. 1 depicts an exemplary carbon causal chain;

FIG. 2 depicts an exemplary data structure representing a carbon causal chain;

FIG. 3 depicts exemplary data structures which could be used to represent transition targets;

FIG. 4 depicts a matrix organization for carbon causal chains;

FIG. 5 depicts a matrix organization for carbon causal chains over time;

FIG. 6 depicts a multi-resource carbon causal chain;

FIG. 7 depicts an interactive display showing interrelated effects of transition targets on carbon causal chains;

FIG. 8 depicts a data structure including a collection of plan data structures;

FIG. 9 depicts an ambition data structure for use in the data structure of FIG. 8;

FIG. 10 depicts a success probability data structure for use in the data structure of FIG. 8;

FIG. 11 is a flow diagram illustrating the processing of data in the data structures of FIGS. 8-10;

FIG. 12 is a flow diagram illustrating optimization of plan data structures using the data structures of some disclosed embodiments;

FIG. 13 is a block diagram depicting a computing resource used in various embodiments; and

FIG. 14 depicts an impact probability tree data structure for use in some illustrated embodiments.

The drawings are not intended to be limiting in any way, and it is contemplated that various embodiments of the invention may be carried out in a variety of other ways, including those not necessarily depicted in the drawings. The accompanying drawings incorporated in and forming a part of the specification illustrate several aspects of the present invention, and together with the description serve to explain the principles of the invention; it being understood, however, that this invention is not limited to the precise arrangements shown.

### DETAILED DESCRIPTION

The following description of certain examples of the invention should not be used to limit the scope of protection provided by this document or any related document. Other examples, features, aspects, embodiments, and advantages of the disclosed technology will become apparent to those skilled in the art from the following description, which is by way of illustration, one of the best modes contemplated for practicing the disclosed technology. As will be realized, the disclosed technology is capable of other different and obvious aspects, all without departing from the scope of what could be implemented by one of ordinary skill in the art without undue experimentation based on this disclosure or of what this disclosure would convey to one of ordinary skill in the art has been invented. Accordingly, the drawings and descriptions should be regarded as illustrative in nature and not restrictive.

It will be appreciated that any one or more of the teachings, expressions, versions, examples, etc. described herein may be combined with any one or more of the other teachings, expressions, versions, examples, etc. that are described herein. The following-described teachings, expressions, versions, examples, etc. should therefore not be viewed in isolation relative to each other. Various suitable ways in which the teachings herein may be combined will be readily apparent to those of ordinary skill in the art in view of the teachings herein.

I. Carbon Causal Chain Model

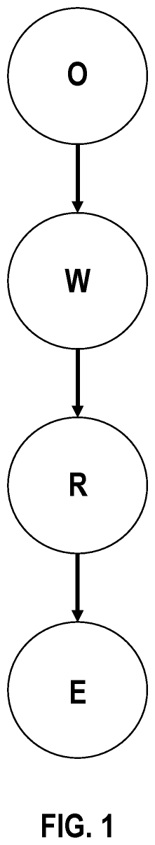

As described in U.S. provisional patent application 63/026,767, which was filed on May 19, 2020, with title APPARATUS, AND METHODS PERFORMED THEREBY, the disclosure of which is hereby incorporated by reference in its entirety, a well-defined and flexible model for achieving the real-world modeling and planning necessary for a mission oriented-approach to tackling climate change can be implemented to describe the causal flow from policy actions to human activities to emissions in terms of a carbon causal chain (CCC). In systems implemented based on this disclosure, such a carbon causal chain may describe a source of carbon emissions in terms of cause and effect from an economic and physics point of view. This may define operations of a machine or process (e.g., vehicle kilometers, heated m² of building space, etc.) that generate work, consume resources, and result in emissions. An exemplary carbon causal chain is depicted in FIG. 1, in which operations may be an activity fulfilling a particular behavior or need (e.g., commuting by car), W may be work, in the mechanical sense of process(es) required to perform the operation with a particular machine or device (e.g., move a person 20 km by internal combustion engine), R may be resources used in performing the necessary work (e.g., 0.2 L petrol), and E may be gasses emitted as a side effect of the resource usage (e.g., 478 g CO₂).

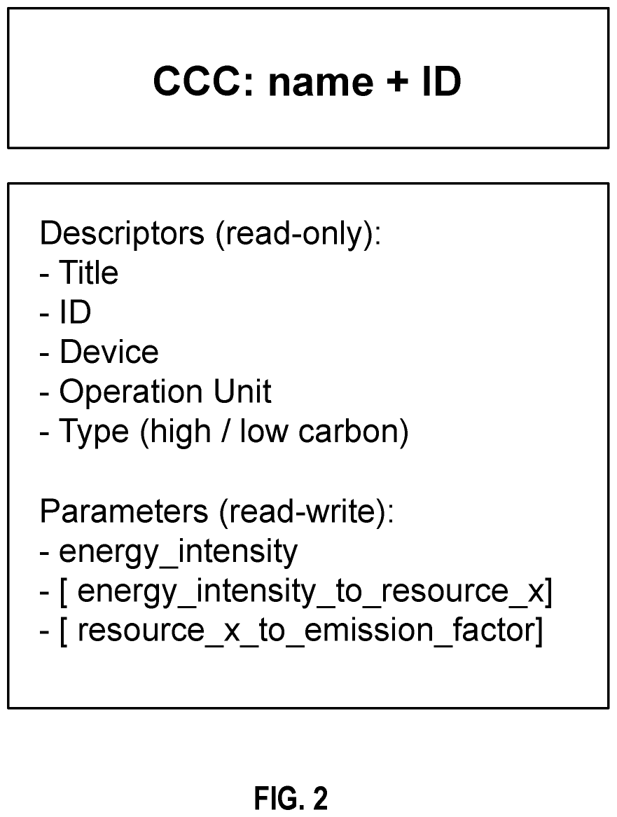

A carbon causal chain such as shown in FIG. 1 may be represented in various ways. For example, in some embodiments, a carbon causal chain may be represented by a data structure such as that shown in FIG. 2. In some embodiments that include data structures along the lines shown in FIG. 2, the data structures could include read-only parameters (i.e., parameters whose values are defined for the CCC and cannot be changed), read-write parameters (i.e., parameters whose values may be changed, either in the course of modeling to show the effect of certain interventions, or through a user interface to make a CCC applicable to a particular scenario), or both. In the embodiment shown in FIG. 2, an exemplary data structure representing a CCC may include the following read-only parameters:
Title—a human-readable label for the particular CCC;
ID—a unique identifier for the CCC that could be used for purposes such as database references, updates, or accesses;
Device—an identifier for a machine used in the CCC;
Operation Unit—the number of instances of a particular operation which take place in the process modeled by the CCC; and
Type—a categorical variable indicating whether the CCC is high or low carbon (or, in embodiments which support different categories, falls into a different category).
   Similarly, a data structure representing a CCC may include the following read-write parameters:
energy_intensity—the amount of energy required to complete a particular operation;
energy_intensity_to_resource—the amount of resource R needed to generate one unit of energy; and

resource_to_emission_factor—the amount of emissions generated per each unit of resource R.

Other types of data structures may also be used to represent CCCs. For example, in some embodiments, a CCC might be represented by a data structure including the parameters set forth in Table 1.

TABLE 1
Exemplary parameters which could be included in a data structure representing a CCC

| Parameter | Description |
|---|---|
| CCC_ID | A unique identifier for a CCC that could be used for purposes such as |
| | database updates or accesses |
| name | A human-readable label for a particular CCC |
| initial_operation | The number of instances of this CCC (e.g., the number of times people |
| | commute 20 km) |
| ccc_type | A category variable indicating if this CCC represents a process which |
| | consumes or supplies energy |
| ccc_subtype | A category variable indicating economic category for processes that |
| | consume energy (e.g., a consumer process or producer process) or |
| | indicating type of energy (e.g., heat energy, electric energy) for processes |
| | that supply energy |
| growth_rate | The rate at which the number of operations of the CCC increases per time |
| | step in the modeling program |
| energy_intensity | The amount of energy required to complete each operation |
| resource_conversion | The amount of resources that are required to create each unit of energy |
| emission_factor | The amount of emissions generated in converting resources to energy |
| secondary_operations | A percentage of the operations for the CCC which may use an additional |
| | resource, along with the additional resource used |

Other types of data structures are also possible and may be implemented in various embodiments. Accordingly, the examples provided above in the context of FIG. 2 and Table 1 should be understood as being illustrative only and should not be treated as limiting.

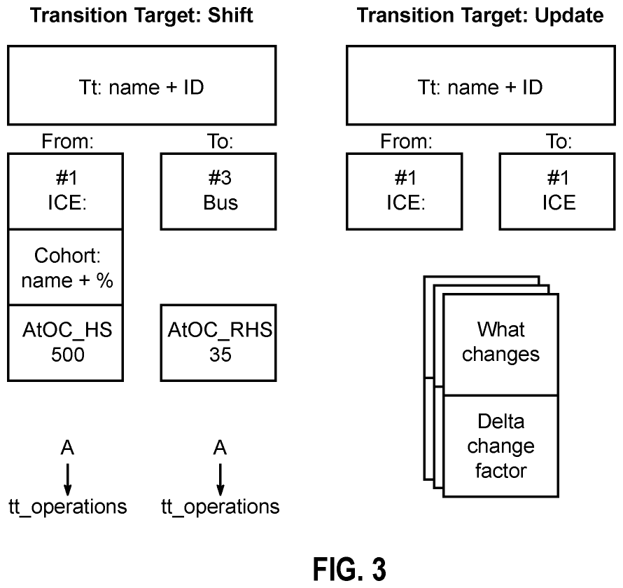

In addition to CCCs, some systems implemented based on this disclosure may also include transition targets (TTs), which could represent transitions of operations from one CCC to another CCC (e.g., for modeling shifts of some transportation events from individual vehicles to mass transit), or they could represent changes in values for CCC parameters (e.g., for modeling shifts within a particular causal chain, such as if residents of an area being modeled begin driving in a more fuel-efficient manner). Examples of data structures which could be used to model each of these types of TTs are shown in FIG. 3, with the Shift TT representing a change from one CCC to another (e.g., from CCC #1, internal combustion engine vehicle transport, to CCC #3, Bus transport), and the Update TT representing a change in CCC parameter values.

Just as there may be variations on representations of CCCs, different representations of TTs may be used in different embodiments. For example, as an alternative to the data structures shown in FIG. 3, some embodiments may represent TTs using data structures having the parameters set forth in Table 2.

TABLE 2
Exemplary parameters which could be included in a data structure representing a TT

| Parameter | Description |
|---|---|
| TT ID | a unique identifier for a CCC that could be used for purposes such as database |
| | updates or accesses |
| title | a human-readable label for a particular TT |
| lhs_ccc_id | the CCC_ID of the CCC to which a particular TT would be applied |
| rhs_ccc_id | the CCC_ID of the CCC which is active after the TT is applied |
| cohort_name | a population label for a unit, item or activity impacted by the TT (e.g., kilowatt |
| | hours, internal combustion engine vehicles, commutes, etc.) |
| cohort | a portion of the cohort (e.g., the portion of all internal combustion engine |
| | vehicles) impacted by the TT |
| activity_name | a human readable label for an activity category for a CCC (e.g., private |
| | transport, freight transport, other transport, etc.) |
| activity unit | units by which the activity identified by activity_name are measured |
| atoc_lhs | operation(s) necessary to complete an activity in a CCC (e.g., distance |
| | traveled per car) before application of the TT |
| atoc_rhs | operation(s) necessary to complete an activity in a CCC (e.g., distance |
| | traveled per car) after application of the TT |
| update_params | identification of parameters in a CCC that would be updated by a transition |
| | target that shifts parameter values |
| update_amounts | identification of amounts by which parameters in a CCC would be changed |
| | by a transition target that shifts parameter values |
| a_shift | a change in activities included in a CCC accomplished by a TT |
| w_lhs | work achieved by a CCC prior to the TT |
| r_lhs | resources used by a CCC prior to the TT |
| e_lhs | emissions generated by a CCC prior to the TT |
| w_rhs | work achieved by a CCC after the TT |
| r_rhs | resources used by a CCC after the TT |
| e_rhs | emissions generated by a CCC after the TT |

Other types of data structures are also possible and may be implemented in various embodiments. Accordingly, the examples provided above in the context of FIG. 3 and Table 2 should be understood as being illustrative only and should not be treated as limiting.

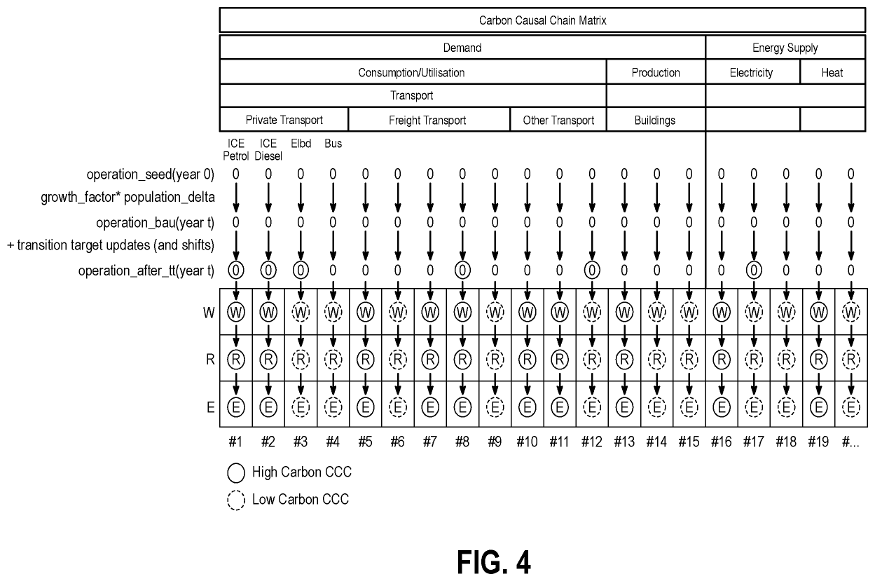

In some embodiments using data structures such as described above to model CCCs and TTs, one or more of those data structures may be organized in a matrix form, such as a matrix that characterizes pre-defined CCCs as well as the effect of various TTs on those CCCs. A graphical example of such a matrix is provided in FIG. 4. As shown in FIG. 4, such a matrix may be organized according to various types and subtypes of the CCCs, and it may include values for a CCC at year 0 as well as at various future times/years (t) under business-as-usual assumptions (operation_bau) and/or under application of various TTs (operation_after_tt). To illustrate how such a matrix may be populated and how the information included in such a matrix may be presented, Tables 3-11 provide exemplary algorithms that may be used for those purposes in some embodiments where CCCs are represented in a form such as shown in Table 1 and stored, for example, in a comma-separated value file called seeds.csv. TTs are represented in a form such as shown in Table 2 and stored in a comma-separated value file called transitions.csv, while transitions to be applied on a yearly basis are stored as a year-by-year matrix in a comma-separated value file called targets.csv.

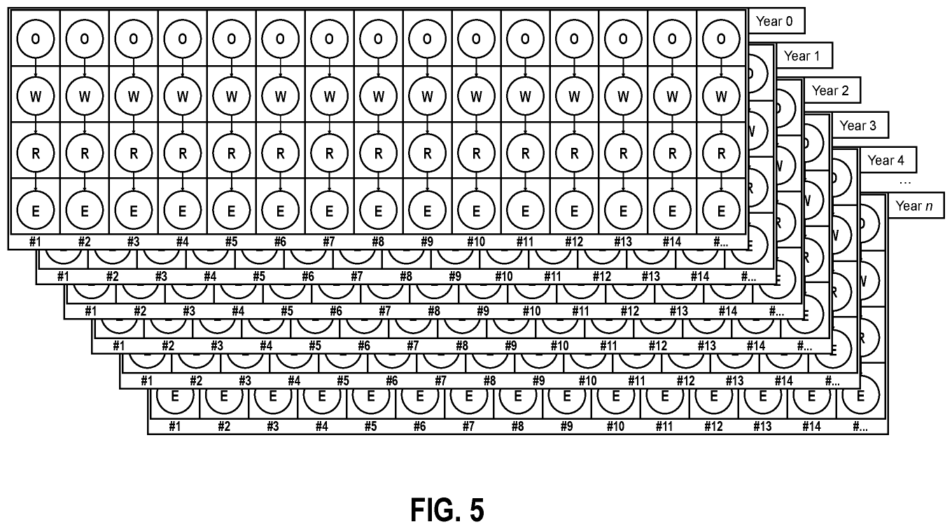

The system then constructs counterparts of the matrix illustrated in FIG. 4 for various points in time (e.g., a sequence of months or years), yielding the higher-dimensional representation shown in FIG. 5. In some embodiments, subsequent years are replicated by making the copy of the matrix from a previous time interval and modifying it, while in others, some or all of the data to fill the matrix for the new time interval is drawn from data sources outside the system resources. In some embodiments, CCC data, cost weights, and even transition targets may be updated to account for projected changes in technology, environment, policy, economics, and other factors as will occur to those skilled in the art.

TABLE 3
Exemplary algorithm for defining parameter values in a given year

```
def get_value_from_parameters( value, year ):
  global parameters
  try:
    value = float(value)
  except:
    pass
  if type( value ) == type( float( ) ) or type( value ) == type( int( ) ):
    # take the value directly
    return value
  elif value[−1] == “%”:
    return float(value[:−1]) / 100
  else:
    # look up value in table and compute it.
    for i in range(len(parameters[year].name)):
      if parameters[year].name[i] == value:
        return get_value_from_parameters(
        parameters[year].value[i], year)
  return “Unknown (%s)” % ( value )
def update_parameter( year, name, value ):
  for i in range(len(parameters[year].name)−1):
    if parameters[year].name[i] == name:
      parameters[year].value[i] = value
initial_parameters = pd.read_csv(“data/parameters.csv”)
parameters = [ initial_parameters.copy( ) for
j in range(number_of_years.value+1) ]
# Compute population growth
import math
population = get_value_from_parameters( “population”, 0 )
population_growth = get_value_from_parameters(
“population_growth”, 0 )
for t in range(1,number_of_years.value+1):
  update_parameter( t, “population”,
  population*math.exp( t * population_growth ) )
def parameter_dict( year ):
  p_dict = { }
  for i in range(len(parameters[year].name)):
    p_dict[parameters[year].name[i]] =
    get_value_from_parameters(parameters[year].value[i],
year)
  return p_dict
html=“<h3>Parameters Year 0</h3>%s<h3>Parameters
Year %s</h3>%s” % (
parameters[0].to_html( ), number_of_years.value,
parameters[number_of_years.value].to_html( ))
widgets.HTML(value=html)
```

TABLE 4
Exemplary algorithm for initializing a CCC matrix with values
from a seeds.csv file and business as usual assumptions

```
def initialize_matrix_from_seed( Matrix, df,
number_of_years, number_of_cccs ):
  import math
  for x in range( 1, number_of_cccs+1 ):
    Matrix[0].loc[x,’operation_bau’] =
    float(df.initial_operation[x])
    Matrix[0].loc[x,’secondary_operations’] =
    df.secondary_operations[x]
    Matrix[0].loc[x,’operation_after_tts’] =
    float(df.initial_operation[x])
    for t in range(1,number_of_years+1):
      Matrix[t].loc[x,’operation_bau’] =
      float(df.initial_operation[x])
    for t in range(0,number_of_years+1):
      Matrix[t].loc[x,’title’] = df.name[x]
      Matrix[t].loc[x,’ccc_type’] = df.ccc_type[x]
      Matrix[t].loc[x,’ccc_subtype’] = df.ccc_subtype[x]
      #Matrix[t].production_delta[x] = 0.0
      Matrix[t].loc[x,’secondary_operations’] =
      df.secondary_operations[x]
      Matrix[t].loc[x,’energy_intensity’] =
get_value_from_parameters(df.energy_intensity[x], t)
      Matrix[t].loc[x,’energy_intensity_bau’] =
get_value_from_parameters(df.energy_intensity[x], 0)
      Matrix[t].loc[x,’resource_conversion’] =
get_value_from_parameters(df.resource_conversion[x], t)
      Matrix[t].loc[x,’resource_conversion_bau’] =
get_value_from_parameters(df.resource_conversion[x], 0)
      Matrix[t].loc[x,’emissionfactor’] =
get_value_from_parameters(df.emission_factor[x], t)
      Matrix[t].loc[x,’emission_factor_bau’] =
get_value_from_parameters(df.emission_factor[x], 0)
cols = [“title”, “ccc_type”, “ccc_subtype”,
“operation_bau”, “operation_after_tts”,
“secondary_operations”, “energy_intensity”,
“energy_intensity_bau”, “resource_conversion”,
“resource_conversion_bau”, “emission_factor”,
“emission_factor_bau”, “W”, “R”, “E”,
“E_bau”, “E_delta”]
import numpy
Matrix = [ pd.DataFrame(
numpy.zeros(shape=(number_of_cccs,len(cols))), columns = cols)
for j in range(number_of_years.value+1)]
for mrow in Matrix:
  mrow.index = np.arange(1, number_of_cccs + 1)
initialize_matrix_from_seed( Matrix, seeds,
number_of_years.value, number_of_cccs )
widgets.HTML(value=“<h3>Year 2</h3>“ +
Matrix[2].to_html(columns=[“title”,
“operation_bau”, “secondary_operations”,
“energy_intensity”, “resource_conversion”,
“emission_factor”], float_format=‘{:10.2f}’.format))
```

TABLE 5
Exemplary algorithm for loading transitions
from a transitions.csv file.

```
transitions = pd.read_csv(“data/transitions.csv”)
transitions.index = np.arange(1, len(transitions) + 1)
transition_count = len( transitions )
transitions[“evaluated_atoc_lhs”] = [ 0 ] * transition_count
transitions[“evaluated_atoc_rhs”] = [ 0 ] * transition_count
def compute_transition( tid, year ):
  # Ensure all atoc values are pre-evaluated
  global transitions
  p_dict = parameter_dict(year)
  transitions.loc[tid,’evaluated_atoc_lhs’] =
  eval( transitions.atoc_lhs[tid], p_dict )
  transitions.loc[tid,’evaluated_atoc_rhs’] =
  eval( transitions.atoc_rhs[tid], p_dict )
  transitions.loc[tid,’cohort’] = float( transitions.cohort[tid] )
  transitions.loc[tid,’lhs_ccc_id’] = int( transitions.lhs_ccc_id[tid] )
  transitions.loc[tid,’rhs_ccc_id’] = int( transitions.rhs_ccc_id[tid] )
for t in range(1,number_of_years.value+1):
    for i in range(1,transition_count+1):
      compute_transition( i, t)
widgets.HTML(value=“<h3>Transitions</h3>“ + transitions.to_html( ))
```

TABLE 6
Exemplary algorithm for loading settings for transitions,
which may be represented as weightings between lhs
and rhs values for each year of a simulation

```
targets = pd.read_csv(“data/targets.csv”)
target_count = len( targets.columns )
def compute_target( tid ):
  global targets
  for t in range(number_of_years.value+1):
    targets.loc[t,’%d’%tid] =
    float( targets[‘%d’%tid][t] )
for i in range(1,target_count):
  compute_target( i )
widgets.HTML(value=“<h3>Shift value (% /
weights)</h3>“ + targets.to_html( ))
```

TABLE 7
Exemplary algorithm for computing the effects of transition targets

```
def ComputeTransitionTargetOperationShift( tid, Matrix, t):
  weight = targets[‘%d’%tid][t]
  lhs_ccc_id = int(transitions.lhs_ccc_id[tid])
  rhs_ccc_id = int(transitions.rhs_ccc_id[tid])
  cohort_factor = transitions.cohort[tid]
  operation_lhs_shift = weight * cohort_factor *
  Matrix[t].operation_bau[lhs_ccc_id]
  # Prevent the Tt from moving more operation than is available:
  if operation_lhs_shift > Matrix[t].operation_after_tts[lhs_ccc_id]:
    operation_lhs_shift = max( 0,
    Matrix[t].operation_after_tts[lhs_ccc_id] )
    weight = operation_lhs_shift / (
    Matrix[t].operation_bau[lhs_ccc_id] * cohort_factor )
    targets.loc[t,’%d’%tid] = weight
  transitions.loc[tid,’a_shift’] = ( weight *
  Matrix[t].operation_bau[lhs_ccc_id] *
cohort_factor ) / transitions.evaluated_atoc_lhs[tid]
  operation_lhs_shift = transitions.a_shift[tid] *
  transitions.evaluated_atoc_lhs[tid] #
theoretically don't need to “recompute” this
  operation_rhs_shift = transitions.a_shift[tid] *
  transitions.evaluated_atoc_rhs[tid]
  Matrix[t].loc[lhs_ccc_id,’operation_after_tts’] −=
  operation_lhs_shift
  Matrix[t].loc[rhs_ccc_id,’operation_after_tts’] +=
  operation_rhs_shift
def ComputeTransitionTargetParameterUpdate( tid, Matrix, t ):
  weight = targets[‘%d’%tid][t]
  lhs_ccc_id = int(transitions.lhs_ccc_id[tid])
  cohort_factor = transitions.cohort[tid]
  update_params = transitions.update_params[tid].split(“,”)
  update_amounts = transitions.update_amounts[tid].split(“,”)
  if len( update_amounts ) != len( update_params ):
    raise Exception(“FATAL: Update params and amounts
    not same length”)
  for i in range(len(update_params)):
    update_param = update_params[i]
    update_amount = get_value_from_parameters(
    update_amounts[i], t )
    if update_param == “cohort”: # in percentage units
      cohort_factor = cohort_factor −
      ( weight * update_amount / 100 )
  for i in range(len(update_params)):
    update_param = update_params[i]
    update_amount = get_value_from_parameters(
    update_amounts[i], t )
  if update_param == “energy_intensity”:
    Matrix[t].loc[lhs_ccc_id,’energy_intensity’] =
    Matrix[t].energy_intensity[lhs_ccc_id] * (
1 − ( cohort_factor * weight * update_amount / 100 ) )
  elif update_param == “emission_factor”:
    Matrix[t].loc[lhs_ccc_id,’emission_factor’] =
    Matrix[t].emission_factor[lhs_ccc_id] * ( 1
− ( cohort_factor * weight * update_amount / 100 ) )
  elif update_param == “resource_conversion”:
    Matrix[t].loc[lhs_ccc_id,’resource_conversion’] =
Matrix[t].resource_conversion[lhs_ccc_id] *
( 1 − ( cohort_factor * weight * update_amount /
100 ) )
  elif update_param == “cohort”:
    pass # already dealt with
  else:
    print(“Warning: unknown update type”)
def ComputeTransitionTarget( tid, Matrix, t ):
  compute_transition( tid , t) # Update transition
  values from parameters - this updating may
account for the fact that, in some embodiments,
energy mix might affect AtOC
  if transitions.lhs_ccc_id[tid] != transitions.rhs_ccc_id[tid]:
  ComputeTransitionTargetOperationShift( tid, Matrix, t) # SHIFT
  else:
  ComputeTransitionTargetParameterUpdate( tid, Matrix, t) # UPDATE
```

TABLE 8
A first representation of an exemplary algorithm for
computing a CCC matrix, including impacts of TTs

For any given year t:

| 1. | Set / update operation_bau for all CCC columns to account for growth: | |
|---|---|---|
| | • | Growth type yes = increases cumulatively as a function of population increase |
| | • | Growth type only = increases as a function of population increase |
| | • | Growth type no = no growth / constant operation |
| 2. | Prepare for applying transition Targets, for all CCC columns: | |
| | • | Set operation_after_tts |
| | • | Calculate energy_intensity, resource_conversion and emission_factor |
| | • | Compute E_bau |
| 3. | Apply Transition Target affects, for each transition: | |
| | • | If shift (LHS != RHS) then update operation_after_tts for LHS / RHS, according to |
| | | the weight, cohort, and computed activity of the Target |
| | • | If update (LHS == RHS) then update parameters for the CCC defined by LHS / |
| | | RHS |
| 4. | For all CCC columns: | |
| | • | Compute the emission E |
| | • | Compute the emission delta E_bau − E |

| | |
|---|---|
| 5. | Compute the emission weighted average for all electricity supply and feed forward |
| | to emission_factor_electricity_current for year t+1 |

TABLE 9
A second representation of an exemplary algorithm for
computing a CCC matrix, including impacts of TTs

```
def compute_ccc_matrix( Matrix, seeds, number_of_cccs, t ):
  for x in range(1,number_of_cccs+1):
    # 1) SET FULL OPERATION STOCK WITH GROWTH
    Matrix[t].loc[x,’secondary_operations’] = seeds.secondary_operations[x]
    ( growth_type, growth_factor ) = seeds.growth_rate[x].split(“,”)
    if growth_type == “yes”:
    Matrix[t].loc[x,’operation_bau’] = float(seeds.initial_operation[x])
    Matrix[t].loc[x,’operation_bau’] += ( get_value_from_parameters(“population”, t) −
get_value_from_parameters(“population”, 0) ) * float(growth_factor)
  elif growth_type == “only”:
    if t > 0: # some embodiments may also support population at time < 0
      Matrix[t].loc[x,’operation_bau’] = ( get_value_from_parameters(“population”, t) −
get_value_from_parameters(“population”, t−1) ) * float(growth_factor)
    else:
      Matrix[t].loc[x,’operation_bau’] = ( get_value_from_parameters(“population”, t+1) −
get_value_from_parameters(“population”, t) ) * float(growth_factor)
  else:
    #No growth.
    pass
  # Prepare operation_after_tts for applying all transition targets of type shift
  Matrix[t].loc[x,’operation_after_tts’] = Matrix[t].operation_bau[x]
  # Update energy_intensity, resource_convesion and emission_factor ready for applying
transition targets of type update
  Matrix[t].loc[x,’energy_intensity’] = get_value_from_parameters(seeds.energy_intensity[x], t)
  Matrix[t].loc[x,’resource_conversion’] =
get_value_from_parameters(seeds.resource_conversion[x], t)
  Matrix[t].loc[x,’emission_factor’] = get_value_from_parameters(seeds.emission_factor[x], t)
  # Finally compute E_bau (i.e. emissions if no transition targets)
  W_bau = Matrix[t].operation_bau[x] * Matrix[t].energy_intensity_bau[x]
  R_bau = W_bau * Matrix[t].resource_conversion_bau[x]
  Matrix[t].loc[x,’E_bau’] = R_bau * Matrix[t].emission_factor_bau[x]
  # 2) COMPUTE EFFECT OF ANY TTs ON OPERATIONS:
  # 2.a) From type = HEAT
  for tid in range(1,transition_count+1):
    if Matrix[t].ccc_type[transitions.lhs_ccc_id[tid]] == “supply” \
    and Matrix[t].ccc_subtype[transitions.lhs_ccc_id[tid]] == “heat”:
      ComputeTransitionTarget( tid, Matrix, t )
  # 2.b) From type = ELECTRICITY
  for tid in range(1,transition_count+1):
    if Matrix[t].ccc_type[transitions.lhs_ccc_id[tid]] == “supply” \
    and Matrix[t].ccc_subtype[transitions.lhs_ccc_id[tid]] == “electricity”:
      ComputeTransitionTarget( tid, Matrix, t )
  # 2.b.i) From type = NOT HEAT OR ELECTRICITY (IF ANY)
  for tid in range(1,transition_count+1):
    if Matrix[t].ccc_type[transitions.lhs_ccc_id[tid]] == “supply” \
    and ( Matrix[t].ccc_subtype[transitions.lhs_ccc_id[tid]] != “heat” \
    and Matrix[t].ccc_subtype[transitions.lhs_ccc_id[tid]] != “electricity” ):
      ComputeTransitionTarget( tid, Matrix, t )
  # 2.c) From type = PRODUCTION.
  touched = [ ]
  for tid in range(1,transition_count+1):
    if Matrix[t].ccc_type[transitions.lhs_ccc_id[tid]] == “consumption” \
    and Matrix[t].ccc_subtype[transitions.lhs_ccc_id[tid]] == “production”:
      ComputeTransitionTarget( tid, Matrix, t )
      touched.append( transitions.rhs_ccc_id[tid] ) # mark RHS as touched - as, in some
embodiments, demand will be handled before non-touched.
  # 2.d) From type = CONSUMPTION (touched by production)
  for tid in range(1,transition_count+1):
    if transitions.lhs_ccc_id[tid] in touched \
    and Matrix[t].ccc_type[transitions.lhs_ccc_id[tid]] == “consumption” \
    and Matrix[t].ccc_subtype[transitions.lhs_ccc_id[tid]] == “demand”:
      ComputeTransitionTarget( tid, Matrix, t )
  # 2.e) From type = CONSUMPTION (not touched by production)
  for tid in range(1,transition_count+1):
    if transitions.lhs_ccc_id[tid] not in touched \
    and Matrix[t].ccc_type[transitions.lhs_ccc_id[tid]] == “consumption” \
    and Matrix[t].ccc_subtype[transitions.lhs_ccc_id[tid]] == “demand”:
      ComputeTransitionTarget( tid, Matrix, t )
  # 3) COMPUTE W / R / E FOR EVERY COLUMN
  for x in range(1,number_of_cccs+1):
    Matrix[t].loc[x,’W’] = Matrix[t].operation_after_tts[x] * Matrix[t].energy_intensity[x]
    Matrix[t].loc[x,’R’] = Matrix[t].W[x] * Matrix[t].resource_conversion[x]
    Matrix[t].loc[x,’E’] = Matrix[t].R[x] * Matrix[t].emission_factor[x]
    # In some embodiments, resource computation may work from a list of resources and
proportions, and would then sum emission of each resource to a single emission value.
    # Compute E_delta
    Matrix[t].loc[x,’E_delta’] = Matrix[t].E[x] − Matrix[t].E_bau[x]
    # Compute new electricity mix value and feed-forward to
“emission_factor_electricity_current” param for following year
    # In some embodiments, this may not be feed-forward, but may determine current year's
“emission_factor_electricity_current” value but would process energy supply before consumption
  if ( t < number_of_years.value ):
    energy_emissions = 0
    energy_operations = 0
    for x in range(1,number_of_cccs+1):
      if Matrix[t].ccc_type[x] == “supply”:
        if Matrix[t].ccc_subtype[x] == “electricity”:
          energy_operations += Matrix[t].operation_after_tts[x]
          energy_emissions += Matrix[t].E[x]
        else:
          if “,” in Matrix[t].secondary_operations[x]:
            sos = Matrix[t].secondary_operations[x].split(“,”)
            if sos[0] == “electricity”:
              percentage = float( float(sos[1][:−1]) / 100 )
              energy_operations += Matrix[t].operation_after_tts[x] * percentage
              energy_emissions += Matrix[t].E[x] * percentage
  update_parameter( t+1, ‘emission_factor_electricity_current’,  energy_emissions /
energy_operations )
# Re-initialize to have clean matrix - which may not be necessary in some embodiments, but
which some embodiments may use when above operations are run repeatedly
#initialize_matrix_from_seed( Matrix, seeds, number_of_years.value, number_of_cccs )
# Call update on all years
for t in range(0,number_of_years.value+1):
  compute_ccc_matrix( Matrix, seeds, number_of_cccs, t )
print(“Matrix computed OK”)
```

TABLE 10
Exemplary algorithm for displaying a CCC matrix.

from IPython.core.display import HTML
# “resource_conversion”,
cols = [“title”, “operation_bau”, “operation_after_tts”,
“energy_intensity”, “emission_factor”,
“W”, “R”, “E”, “E_bau”, “E_delta”]
children =
[widgets.HTML(value=Matrix[i].to_html(columns=cols,float_format=‘{:10.2f}’.format)) for i in
range(number_of_years.value+1)]
tab = widgets.Tab( )
tab.children = children
[tab.set_title(title=“%d”%i,index=i) for i in
range(number_of_years.value+1)]
tab

TABLE 11
Exemplary algorithm for generating emission and operation graphs

```
def graph_emissions( ccc_ids ):
  x = range(number_of_years.value+1)
  fig, axs = plt.subplots(len(ccc_ids), 2,
  figsize=(18, 4*len(ccc_ids)), dpi=75,)
  fig.subplots_adjust(hspace=1.2, wspace=0.3)
  #print(axs)
  for t in range(len(ccc_ids)):
    axs[t][0].set_title( Matrix[i].title[t+1] )
    axs[t][0].set_ylabel(‘CO2-e’)
    axs[t][0].set_xlabel(‘Emissions’)
    axs[t][0].plot( x, [Matrix[i].E[t+1]
    for i in x], label=“Emissions” )
    axs[t][0].plot( x, [Matrix[i].E_bau[t+1]
    for i in x], label=“Emissions (BAU)”, linestyle=‘--’ )
    axs[t][1].set_title( Matrix[i].title[t+1] )
    axs[t][1].set_ylabel(‘#’)
    axs[t][1].set_xlabel(‘Operations’)
    axs[t][1].plot( x, [Matrix[i].operation_after_tts[t+1]
    for i in x], label=“Operations” )
    axs[t][1].plot( x, [Matrix[i].operation_bau[t+1]
    for i in x], label=“Operations (BAU)”,
linestyle=‘--’ )
    axs[t][0].get_yaxis( ).set_major_formatter(
      matplotlib.ticker.FuncFormatter(lambda x, p: format(int(x), ‘,’)))
    axs[t][1].get_yaxis( ).set_major_formatter(
      matplotlib.ticker.FuncFormatter(lambda x, p: format(int(x), ‘,’)))
    plt.show( )
graph_emissions(range(1,number_of_cccs+1))
```

Using algorithms such as provided above in Tables 3-11, a system could be implemented that would allow policymakers to see the results of potential interventions and to ensure that proposed actions align with target goals. For example, a server-based system could be implemented which would allow a user to submit requests and other information (e.g., parameter values, goals, action) and would provide the user with outputs showing how the polices related to that information (e.g., maintain business as usual, intervene to promote a particular transition) would impact their goals.

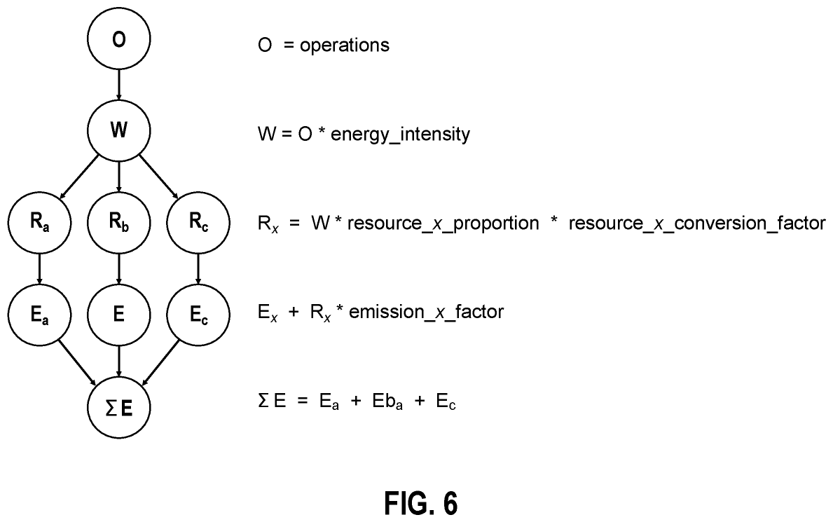

Of course, it should be understood that, while the above disclosure has provided examples that could be used in implementing mission-oriented approaches to combating climate change, those examples are intended to be illustrative only, and should not be treated as limiting on the scope of protection provided by this document or any related document. For example, while the exemplary CCC illustrated in FIG. 1 modeled a single resource for accomplishing the work required for the operations, some embodiments may support multiple resources, such as using a model as shown in FIG. 6, where an activity may consume multiple resources (Rₓ) resulting in multiple emissions (Eₓ), that could be summed together to show the CCC's ultimate impact. As another example, while may of the illustrations described above focused on CCCs for personal transport, other types of CCCs may also be used in some embodiments. For instance, some embodiments may support CCCs such as those set forth in Table 12.

TABLE 12
Exemplary CCCs

ICE Vehicles
EV Vehicles
Bus
Train
Walking/Cycling
E-Meetings
ICE light trucks
EV light trucks
ICE heavy trucks
EV heavy trucks
Freight ship
Freight train
Heating new domestic buildings (natural gas, electricity)
Heating new domestic buildings heat pumps
Heating existing domestic buildings district heating
Heating new commercial buildings (natural gas, electricity)
Heating new commercial buildings heat pumps
Heating new commercial buildings district heating
Building new domestic buildings
Building new low carbon domestic buildings
Building new commercial buildings
Building new low carbon commercial buildings
District heating high carbon
District heating low carbon
Electricity - Coal
Electricity - Natural Gas
Electricity - Biofuels
Electricity - Waste
Electricity - Nuclear
Electricity - Hydro
Electricity - Wind
Electricity - Solar

Additional types of CCCs, as well as relationships between them are also possible. For example, some embodiments may support CCCs that represent activities such as transporting and/or supplying stored energy (e.g., refining and transporting gasoline). As an additional example, CCCs that represent land use may be connected to CCCs that represent changes in land use to reflect that CCCs that represent changes in land use will affect use of the land at future time intervals (e.g., when a forest is clear-cut for agriculture use, there will be a one-time climate effect because of activities during the transition, but there will also be ongoing effects on the climate due to the changes that are made to the land itself). In such embodiments, the various CCCs for generating and making stored energy available could be treated as different types of production CCCs that would provide resource inputs other CCCs might consume.

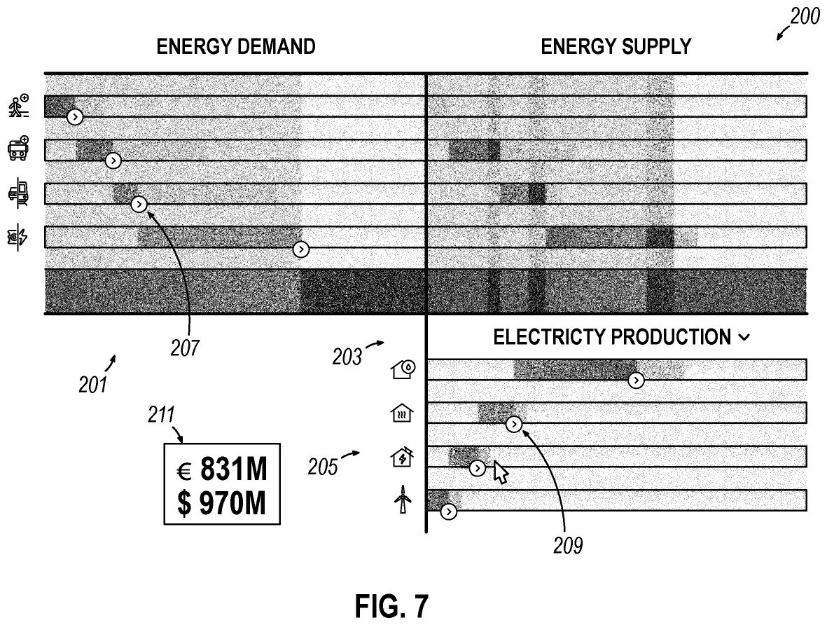

FIG. 7 depicts an interactive tool 200 that uses the portions of the system disclosed above to show interactions between transition targets, cost, and release of carbon or greenhouse gasses (GHG). Demand section 201 of interactive tool 200 displays a group of demand-side transition targets, wherein each horizontal bar includes a slider 207 that a user can move between a minimal (often a status quo, or “business as usual”) scenario and a maximum (possible) adjustment scenario. As the slider 207 for a particular transition target is moved to indicate a different adoption rate of that transition target, the range of possibilities available for other transition targets changes automatically. For example, if every kilometer traveled by commuters is on mass transit, the range of possible change in shifting from gasoline to electric vehicles will be much smaller, as will the possible effect of that change. In some implementations, manual adjustment of the slider 207 for one transition target causes other transition targets to be adjusted to keep their slider 207 (that is, the selected degree of adoption of that other transition target) proportional to its position within the available range before the change. In other implementations, the other slider 207 retains its position on the overall bar, while in still other implementations, still different adjustments will be made as will occur to those skilled in the art.

Energy supply section 203 of interactive tool 200 illustrates the amount of energy used (for example, in kilowatt-hours) corresponding to the transition targets in demand section 201 and the respective positions of sliders 207. In the illustrated embodiment, different colors, shades, or other indications show the proportion of “clean” and “dirty” energy used in the corresponding CCCs. In other embodiments, more and/or different levels of “cleanliness” or other breakdowns will be illustrated as will occur to those skilled in the art.

Energy production section 205 of interactive tool 200 includes a bar illustrating the range of amounts of energy that can be supplied by different production resources available in the system. A user can adjust a slider 209 associated with each type of energy to select the amount of energy generated using each technique within the range provided. As with sliders 207, movement of any given slider changes the available range for other sliders 209 as well as the clean/dirty and other data shown in energy supply section 203.

In the illustrated embodiment, a cost per kilowatt hour of energy for each type of energy production/supply is obtained from an outside data source for the particular location being studied, and the total energy cost of the selected targets is shown in cost output box 211. In some embodiments, the marginal cost of capital improvements is included as well, and in some embodiments, that cost is presented separately. In various embodiments, other data is added, changed, or overridden by other data sources (e.g., data accessible/provided by API, scraped from a webpage, or in another database), and in some embodiments, the data used in the model is modified over time based on external projections and/or changes to supply and demand that result from the present model. Still other adjustments to the various values in the system will be made in other implementations as will occur to those skilled in the art.

With the computing system arranged according to any of the various embodiments with any (or none) of the modifications given herein, some embodiments further include programming to perform optimization and/or balancing operations using the system. For example, if cost data is integrated into the system, transition targets may be selected and/or adjusted to achieve certain carbon output goals within a certain period of time at the lowest possible cost. In some embodiments, the system identifies one such minimum, while in others, multiple combinations of transition targets are identified. In some embodiments, an absolute minimum is identified, while in others, one or more local minima are identified. In this optimization process, the system may use a Monte Carlo method, simulated annealing, curve following, or other technique as will occur to those skilled in the art. Machine learning techniques may be applied to this process to improve performance (in results and/or search technique) over time as will occur to those skilled in the art.

II. Climate Plans

As scientific knowledge of climate change has increased over the last few decades, individuals, organizations, government agencies, nongovernmental organizations, and intergovernmental organizations have debated (and, in some cases, taken) action to reduce the effect of human activity on the climate. Unfortunately, the climate is an extremely complex and ever-changing system that might be affected to one extent or another by every action taken by every person throughout their entire lives. Thus, evaluating the near-infinite combinations of actions and inactions, priorities, policies, and other choices soon becomes overwhelming.

Part of the challenge here lies in considering and comparing the possible plans with each other. While some actions under a first plan might have a marked long-term effect, other actions may have direct consequences only in the short term, then have indirect consequences over time. Some investments affect the climate-influencing activities of a small number of people, while others affect the activities of many more. Some investments require a small amount of capital, while others require more. Some investments rely on uncertain contingencies to achieve amazing results, while others are nearly certain to achieve moderate results. As individuals, organizations, government agencies, nongovernmental organizations, and intergovernmental organizations evaluate plans, the invention provides a computational framework and data tagging to prioritize them and select among them.

III. Data Structures

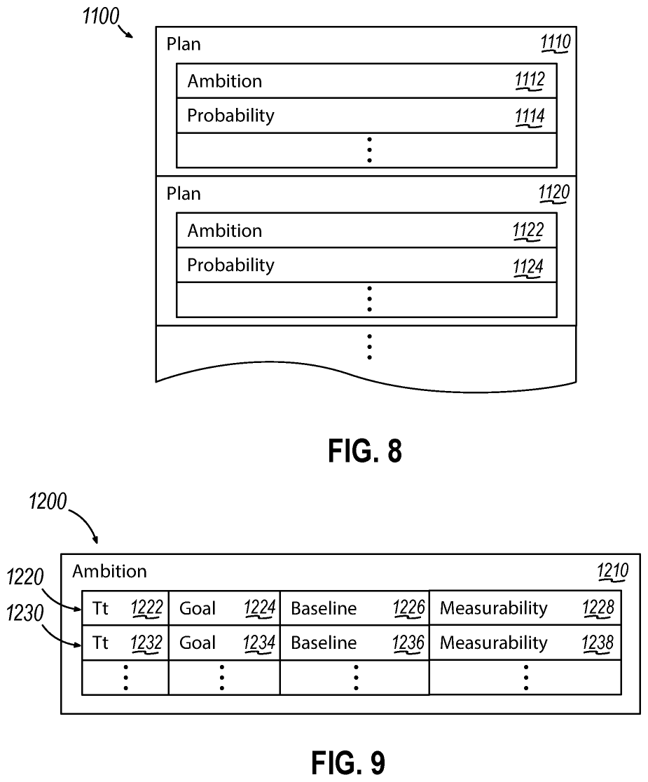

Turning to the exemplary embodiment shown in FIG. 8, a memory holds data structure (1100), which comprises a plurality of climate-affecting plans (1110, 1120, etc.). Each plan (1110, 1120) includes an “ambition” data structure (1112, 1122) characterizing the potential overall net benefit of the plan (1110, 1120)). Each plan (1110, 1120) also includes a “probability” data structure (1114, 1124) characterizing the likelihood that such net benefit will be achieved. Each of these data structures (1100, 1110, 1112, 1114, 1120, 1122, 1124) may comprise additional data and may be processed in a wide variety of ways, including the additional data and processing discussed in the exemplary embodiments described herein, as will occur to one of skill in the art in view of this disclosure.

Turning to the exemplary embodiment shown in FIG. 9, a memory holds “ambition” data structure (1210), which comprises one or more ambition components (1220, 1230). Each ambition component (1220, 1230) includes first “transition target” data (1222, 1232), measurable goal metric (1224, 1234), baseline measurement metric (1226, 1236), and a measurability metric (1228, 1238), each of which provides some numeric characterization of that aspect of the first transition target (1222, 1232). The first transition targets (1222, 1232), which could represent transitions of operations from one “carbon causal chain” (CCC) to another CCC (e.g., for modeling shifts of some transportation events from individual vehicles to mass transit), or they could represent changes in values for CCC parameters (e.g., for modeling shifts within a particular causal chain, such as if residents of an area being modeled begin driving in a more fuel-efficient manner). Additional explanation of transition targets, CCCs, and data structures which could be used to model each of these types of transition targets are all shown in U.S. Provisional App. No. 63/083,175, filed on Sep. 25, 2020, with title “Matrix-Implemented Computational Modeling Framework,” the entirety of which is incorporated herein by reference as if fully set forth.

The goal (1224, 1234), baseline (1226, 1236), and a measurability (1228, 1238) metrics may each be rated against corresponding entries in a larger database; may characterize a proportion (on a linear, logarithmic, inverse (e.g., [n*(1−a/x)]) or other scale) between extremes, objective endpoints, or each other; and/or may comprise a subjective evaluation of those aspects of the first transition target (1222, 1232). The measurability metric (1228, 1238) in some embodiments directly represents a degree of certainty (e.g., reliability) that individual measurements of the goal metric will reflect real values, a degree of certainty that the measurements to be taken will actually reflect a change in the quantity sought to be affected, some other quantity, and/or some combination thereof as will occur to those skilled in the art.

Each first transition target (1222, 1232) involves a primary indicator of progress in the transition. For example, a transition target (1222, 1232) regarding transition from miles driven in vehicles with internal combustion engines to bicycle miles might use highway vehicle counter data as a primary indicator with a baseline metric (1226, 1236) indicating 436 million vehicle trips and a goal metric (1224, 1234) indicating 327 million vehicle trips. The measurability metric (1228, 1238) may indicate the “moderate” quality of the association between the measured highway vehicle counter data and the desired transition from miles driven in internal combustion engine (ICE) vehicles to bicycle miles.

In some embodiments, each of a collection of implementations of identified strategies or endeavors affects the driver of the primary indicator of the transition target. In some of these embodiments, the system characterizes those relationships (that is, how the implementations numerically affect the drivers and how the drivers affect the related primary indicator) to predict how the effect of the effort is likely to be quantified. This may be a static function of a single variable, the function might be multivariate, it might depend on other information or values, and it might vary over time (for example, marginally higher or longer-lasting efforts may yield diminishing returns). Further, the net benefit of certain efforts may be affected by other policy changes or eventualities (for example, efforts to convert a certain number of passenger-miles from ICE vehicles to electric vehicles using a gasoline tax may be affected by changing subsidies of ethanol fuel or installation of a public transportation system), so this function mapping implementations to strategies, endeavors, or drivers may be complex, time-varying functions that account for such changes or eventualities as will be appreciated by those skilled in the art.

Transition targets and other elements of the data structures in various embodiments are also encoded with data regarding “co-benefits” associated with the transition target or other element. These co-benefits characterize other relevant effects, or externalities, that would or could result from achievement of the transition target, quantified in economic terms. For example, a reduction in distance driven in favor of more bicycle commuting would have a positive effect on the health of residents and a corresponding reduction in healthcare costs. Furthermore, the same transition would reduce air pollution in the region of interest and surrounding regions, which would improve the health of residents in all of those areas, improve productivity throughout, and increase trade in the jurisdiction making the plan. On the other hand, outgassing from the laying of concrete for bicycle paths would have its own environmental effects, and maintenance of the bicycle paths would have further, ongoing environmental effects. In preferred embodiments, all of these net costs and benefits would be measured relative to the cost of inaction, including status-quo expenses and maintenance and projected costs of mitigating the effects of climate change that would result from that inaction.

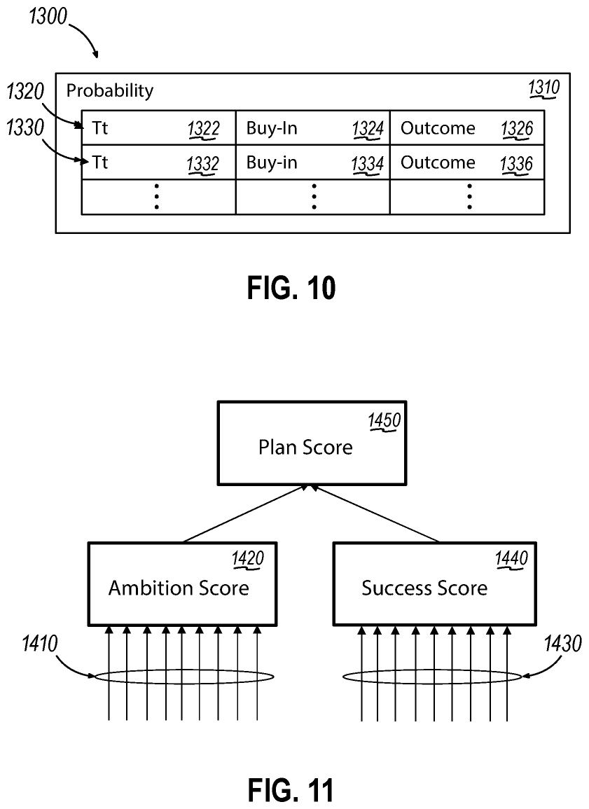

Turning to the exemplary embodiment shown in FIG. 10, a memory holds success “probability” data structure (1310), which comprises one or more success probability components (1320, 1330). Each success probability component (1320, 1330) includes “transition target” (1322, 1332) data, “buy-in” data (1324, 1334) and “outcome” data (1326, 1336). Second transition target data (1322, 1332) may be the same as first transition target data (1222, 1232), or it may include more, fewer, or different data components. “Buy-in” data (1324, 1334) characterize and quantify the buy-in to the associated second transition target data (1322, 1332), such as the type and number of stakeholders who have participated in developing the transition target (1322, 1332), the size and prominence or influence of key groups who have touched key parameters in the transition target (1322, 1332), and other data as will occur to those skilled in the art.

“Outcome” data (1326, 1336) in some embodiments include data characterizing an evaluation of successful implementations of the particular transition target (1322, 1332) and perhaps other transition targets as well. In some embodiments, “outcome” data (1326, 1336) will not characterize net changes to emissions expected to result from the transition target (1322, 1332) but will characterize maintenance of the transition target (1322, 1332) by the frequency and/or significance of adjustment and updating of its parameters. In some embodiments, the positive effect of updating will “cool” over time, resulting in a score benefit for transition targets that are regularly maintained and updated. The values related to various second transition targets (1322, 1332) in success probability data structure (1310) are combined to obtain an outcome value by weighted averaging, least-distance weighting, cluster analysis, or other analysis as will occur to those skilled in the art.

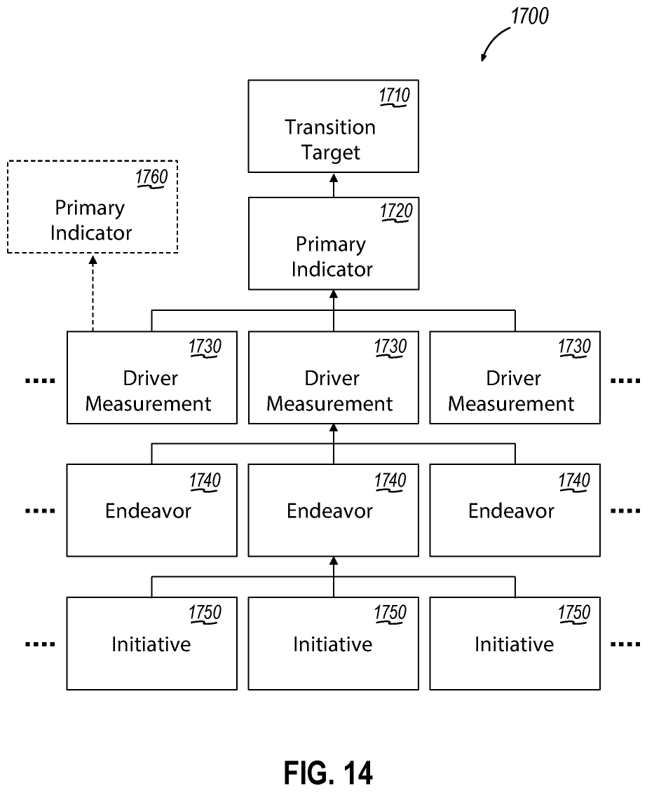

In some embodiments, outcome data (1326, 1336) related to each transition target (1322, 1332) comprises an impact probability tree (1700) like that shown in FIG. 14. In this illustrated embodiment, each transition target (1710) is part of a plan for changing the activities of a person, organization, country, or region from a baseline state to a goal state, particularly in terms of greenhouse gas emissions, carbon footprint, and the like. The transition target (1710) is defined in terms of a primary indicator (1720), a quantitative characterization of the activity being changed. The change in this primary indicator (1720) under the relevant plan is driven by one or more subsidiary changes in certain “drivers,” or targeted changes in measurable facts (driver measurements (1730)) that contribute to the targeted change in the primary indicator (1720).

Each driver measurement (1730) described in the plan under the transition target (1710) is supported by one or more endeavors (1740), or high-level policy changes designed to affect the driver. Each endeavor (1740) comprises one or more initiatives (1750), or specific policy changes or similar government programs that will be implemented under the plan to achieve the endeavor (1740).

In some variations on this embodiment, there are more or fewer layers of subdivision in the breakdown of activities and the analysis of probabilities and results, and in some multiple “primary indicators” relate to each (or at least one or more) transition target. In some variations, the tree has the same depth along all branches, while in others some branches are more or less deep than others. In some embodiments, a given unit (such as a driver measurement (1730)) relates to more than one higher-level unit (such as primary indicators (1720, 1760)), and in various ones of these implementations the higher-level units are of the same or different levels in their own trees. In some embodiments, the higher-level units are part of different data structures characterizing different plans, making the overall, multiple-plan data structure a directed acyclic graph (DAG) rather than a tree.

The impact probability tree (1700) data structure is designed to provide information from which the system can determine the likelihood that the transition target (1710) will be achieved. Therefore, impact probability tree (1700) in the illustrated embodiment also includes information in each initiative block (1750) characterizing the likely effect of the initiative (1750) on the overall policy endeavor (1740) and, in some variations of the embodiment, a probability or probability distribution characterizing the likelihood of that result. This “likely effect” and probability data is taken in some embodiments from human input and estimation (e.g., entered by experts, executives, or bureaucrats in the relevant field), while in others it is interpolated, extrapolated, or otherwise automatically derived from static or dynamic databases of information about comparable situations and efforts, and/or machine learning or other artificial intelligence processing of the available data. Similarly, each endeavor block (1740) includes information characterizing the likely effect of the endeavor (1740)—including all of the contributing initiatives (1750)—on the driver measurement (1730) and, in some variations of the embodiment, a probability or probability distribution characterizing the likelihood of that result. The system combines the composite information under each driver measurement (1730) to yield the likely result as to the primary indicator (1720) and, in turn, the transition target (1710).

In various embodiments, the information stored in and/or passed up the impact probability tree (1700) comprises a probability distribution over the range of potential results of each block/branch. In some embodiments, the information stored in and/or passed up the impact probability tree (1700) comprises an expected value for the result and/or a likelihood of a particular result. In some embodiments, the information is a single value, a function, a plurality of values, or a vector or other data structure, while in other embodiments it takes another form as will occur to those skilled in the art.

IV. Processing of Data Structures

Turning to FIG. 11, the present system processes the ambition data structures (1410) by evaluating the ambition components (1220, 1230) associated with respective transition targets (1222, 1232) in a plan. In various embodiments, the system calculates a product of respective goal (1224, 1234), baseline (1226, 1236), and measurability (1228, 1238) metrics for each first transition target (1222, 1232), while in others the metrics are summed or otherwise combined using mathematical techniques as will occur to those skilled in the art. The system then combines the values from all of the ambition components (1220, 1230) by taking their average, weighted average, root-of-sum-of-squares, [(goal−baseline)*measurability], or other technique as will occur to those skilled in the art. In some embodiments, the resulting ambition score (1420) is solely a mathematical function of respective scores derived from respective ambition components (1220, 1230), while in others the ambition score (1420) is a function of both individual metrics from within the ambition components (1220, 1230) and a combination of all of them. For example, the ambition score (1420) may start with a combined metric as discussed above, then may be weighted by a “moonshot” factor characterizing the total ambition represented by the combination, for example, the sum of the differences between the respective goals (1224, 1234) and baselines (1226, 1236) for each of the transition targets (1222, 1232).

Similarly, the present system processes the success probability data structures (1430) by evaluating the success probability components (1320, 1330) associated with respective second transition targets (1322, 1332) in the plan. In various embodiments, the system calculates a product of respective buy-in (1324, 1334) and outcome (1326, 1336) metrics for each second transition target (1322, 1332), while in others the metrics are summed or otherwise combined using mathematical techniques as will occur to those skilled in the art. The system then combines the values from all of the success probability components (1320, 1330) by taking their average, weighted average, root-of-sum-of-squares, or other technique as will occur to those skilled in the art. In some embodiments, the resulting success probability score (1440) is solely a mathematical function of scores derived from respective success probability components (1320, 1330), while in others success probability score (1440) is a function of both individual metrics from within the success probability components (1320, 1330) and a combination of all of them. For example, the success score (1440) may start with a combined metric as discussed above, then may be weighted or adjusted by an “organizational” factor characterizing the total breadth of buy-in represented by the combined second transition targets (1322, 1332) in the plan, the number of persons affected by or participating in the second transition targets (1322, 1332), or other factor as will occur to those skilled in the art. Note that, while some embodiments only calculate a single score for a plan comprising multiple transition targets, other embodiments calculate multiple scores or other data elements (that is, an n-dimensional vector) for such a plan, and still other embodiments calculate one or more scores or a vector for each transition target, all as will occur to those skilled in the art.

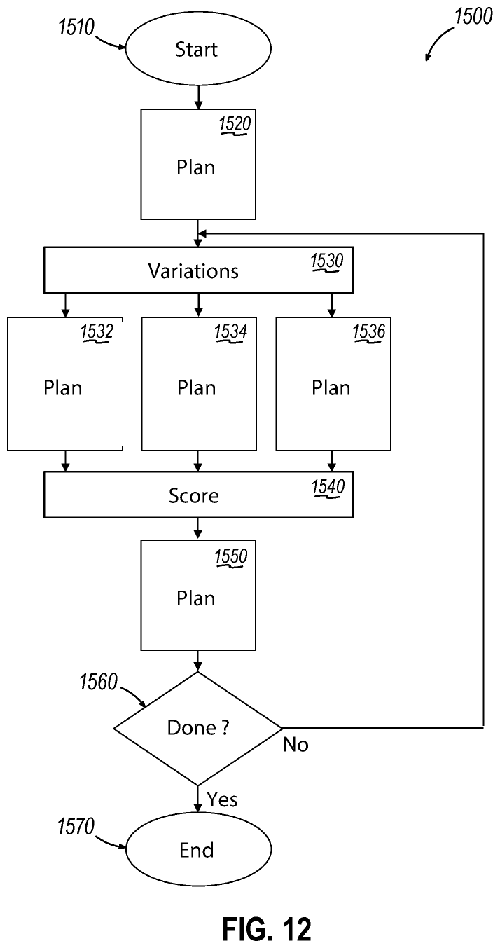

With the computing system arranged according to any of the various embodiments with any (or any combination, or none) of the modifications given herein, some embodiments further include programming to perform optimization and/or balancing operations using the system. In the example (1500) illustrated in FIG. 12, operation starts (1510) with an initial plan (1520) including a collection of transition targets, which may be selected randomly and/or manually based on available resources and policy preferences. Variations (1530) block creates plan variations (1532, 1534, 1536) of plan (1520) by systematically and/or randomly changing those transition targets. Each of the plan variations (1532, 1534, 1536) is scored (1540) as described herein, and one or more top-scoring plans (1550) are selected. In some embodiments, further adjustment-and-scoring rounds are applied (1560) to optimize plan scoring to local or global extremes. In some embodiments, the system identifies one such minimum/maximum, while in others, multiple combinations of transition targets are identified. In some embodiments, an absolute minimum/maximum is identified, while in others, one or more local minima/maxima are identified. In any event, the system (1500) outputs the resulting plan(s) (1550) when it reaches terminal endpoint (1570). In this optimization process, the system may use a Monte Carlo method, simulated annealing, curve following, a genetic algorithm, or other technique as will occur to those skilled in the art. Machine learning techniques may be incorporated into this process to improve performance (in results and/or search technique, for example, by changing the scoring functions used in scoring block (1540)) over time as will occur to those skilled in the art.

V. Applied Models

In one such class of embodiments, modelling and optimization of the plan is performed by an application of agent-based modeling, or ABM. For example, one embodiment uses an agent-based stock-flow consistent (SFC) accounting model over time steps of one calendar quarter to one calendar year. Multidimensional matrices (see, for example, those described in parts I and III above) model financial transactions, physical attributes, and the resources involved in carbon-emitting activities and how they all change over time. Characterizing transitions and/or economic activities as the “agents” in the model, rules defining the agents' “bounded rationality” iteratively adjust the activities of production, consumption, and asset-holding with the goal of increasing the effect of initiatives (or endeavors, measurable drivers, or primary indicators), successful achievement of one or more transition targets themselves, or minimizing carbon emissions as a whole, all while maintaining or growing activity. The agents' strategy options encoded in the system may be in any one or more of these categories:
shifting the underlying mechanism by which the activity is performed to a greener alternative (e.g., from ICE vehicles to electric vehicles),
optimizing the carbon-emitting resource used by improving the efficiency of the underlying mechanism (e.g., improving the energy conversion efficiency in electric vehicles),
reducing the energy usage by the underlying mechanism (e.g., improving the load factor for light trucks), and
resource-shifting by maintaining activity and the underlying mechanism, but using a different mix of resources (e.g., shifting from gasoline to biodiesel),
   though other implementations will use more, fewer, or different categories or strategies as will occur to those skilled in the art. For example, in some embodiments, agents may choose different economic strategies or strategies for interactions with respect to resources. Each agent in the model chooses a strategy as a function of the state of the system, as is understood by those skilled in the art. The agents' adaptations may not achieve a global extreme, but they may simply seek a state that is “good enough,” for example, a state that is expected to achieve the overall climate-related target within a prescribed margin of likelihood.

This exemplary model accounts for the co-benefits described above alongside traditional economic dynamics and optimization of plan scoring, as will occur to those skilled in the art. In addition to accounting for financial transactions and economic stocks, the AB-SFC model ensures that each carbon abatement in the plan is a transition from one activity (e.g., a high-carbon activity) to another activity (e.g., a lower-carbon alternative) while supporting the necessary overall level of activity. In some sense, this is a simple optimization problem, but in another, the optimization process in some embodiments is achieved by establishing the strategy selection rules as a competition between the agents to achieve the greatest positive climate and/or economic impact while maintaining and growing activity. This focus on the “meso” timescale and activity helps, in some embodiments, to reap the benefits of considering local action (where decisions are actually made) without losing sight of the cumulative effects of those actions and broader goals of the system.

VI. General

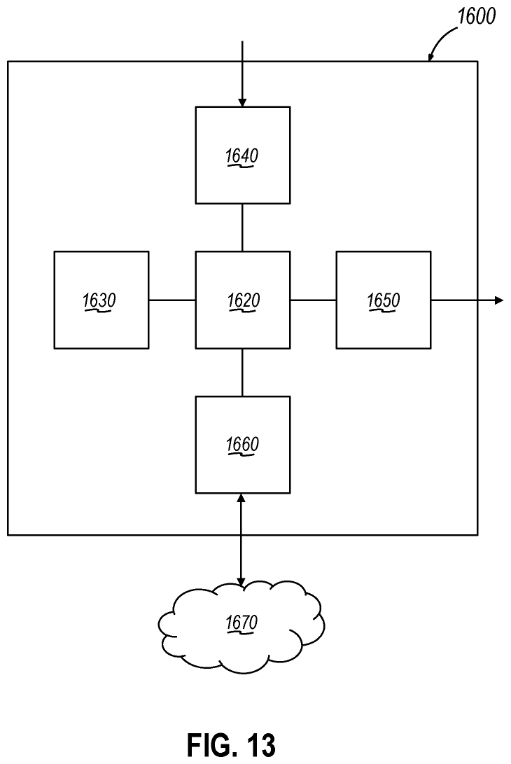

In some embodiments of the systems described herein, the computing/processing resources/devices that are applied generally take the form of a mobile, laptop, desktop, or server-type computer, as mentioned above and as will occur to those skilled in the art. The “computer” 1600, as this example will generically be referred to with reference to FIG. 13, includes a processor 1620 in communication with a memory 1630, input interface(s) 1640, output interface(s) 1650, and network interface 1660. Memory 1630 stores a variety of data but is also encoded with programming instructions executable to perform the functions described herein. Power, ground, clock, additional communication connections, and other signals and circuitry (not shown) are used as appropriate for each context as will be understood and implemented by those skilled in the art.

The network interface 1660 connects the computer 1600 to a data network 1670 for communication of data between the computer 1600 and other devices attached to the network 1670. Input interface(s) 1640 manage communication between the processor 1620 and one or more touch screens, sensors, pushbuttons, UARTs, IR and/or RF receivers or transceivers, decoders, or other devices, as well as traditional keyboard and mouse devices. Output interface(s) 1650 may provide a video signal to a display (not shown), and may provide signals to one or more additional output devices such as LEDs, LCDs, or audio output devices, local multimedia devices, local notification devices, or a combination of these and other output devices and techniques as will occur to those skilled in the art.

The processor 1620 in some embodiments is a microcontroller or general-purpose microprocessor that reads its program from the memory 1630. The processor 1620 may be comprised of one or more components configured as a single unit. When of a multi-component form, the processor may have one or more components located locally and/or one or more components located remotely relative to the others, in any case operating using uniprocessor, symmetric multiprocessor, asymmetric multiprocessor, clustered, or other technique as will occur to those skilled in the art. One or more components of the processor may be of the electronic variety including digital circuitry, analog circuitry, or both. In some embodiments, the processor (or one or more components thereof) is of a conventional, integrated circuit microprocessor arrangement, such as one or more CORE i5, i7, or i9 processors from INTEL Corporation of 2200 Mission College Boulevard, Santa Clara, Calif. 95052, USA, or BEEMA, EPYC, or RYZEN processors from Advanced Micro Devices, 2485 Augustine Drive, Santa Clara, Calif. 95054, USA. In alternative embodiments, one or more reduced instruction set computer (RISC) processors, application-specific integrated circuits (ASICs), general-purpose microprocessors, programmable logic arrays, or other devices may be used alone or in combinations as will occur to those skilled in the art.

Likewise, the memory 1630 in various embodiments includes one or more types such as solid-state electronic memory, magnetic memory, or optical memory, just to name a few. By way of non-limiting example, the memory 1630 can include solid-state electronic Random Access Memory (RAM), Sequentially Accessible Memory (SAM) (such as the First-In, First-Out (FIFO) variety or the Last-In First-Out (LIFO) variety), Programmable Read-Only Memory (PROM), Electrically Programmable Read-Only Memory (EPROM), or Electrically Erasable Programmable Read-Only Memory (EEPROM); an optical disc memory (such as a recordable, rewritable, or read-only DVD or CD-ROM); a magnetically encoded hard drive, floppy disk, tape, or cartridge medium; a solid-state or hybrid drive; or a plurality and/or combination of these memory types. Also, the memory in various embodiments is volatile, nonvolatile, or a hybrid combination of volatile and nonvolatile varieties.

Computer programs implementing the methods described herein will commonly be stored and/or distributed either on a physical distribution medium such as DVD-ROM or via a network distribution medium such as an internet protocol or token ring network, using other media, or through some combination of such distribution media. From there, they will often be copied to a solid-state drive, hard disk, non-volatile memory, or a similar intermediate storage medium. When the programs are to be run, they are loaded either from their distribution medium or their intermediate storage medium into the execution memory of the computer, configuring the computer to act in accordance with the method described herein. All of these operations are well known to those skilled in the art of computer systems.

When an act is described herein as occurring “as a function of” or “based on” a particular thing, the system is configured so that the act is performed in different ways depending on one or more characteristics of the thing. When the act is described herein as occurring “solely as a function of” or “based exclusively on” a particular thing, the system is configured so that the act is performed in different ways depending only on one or more characteristics of the thing.

References herein to a “data structure” refer equally to collections of data in contiguous memory, various semantically related data elements separated in different memory locations or memory devices, references (of any degree of indirection) to any of the above, and any combination of the above.

It should be understood that any of the examples described herein may include various other features in addition to or in lieu of those described above. By way of example only, any of the examples described herein may also include one or more of the various features disclosed in the prior application, which is incorporated by reference herein.

It should be understood that any one or more of the teachings, expressions, embodiments, examples, etc. described herein may be combined with any one or more of the other teachings, expressions, embodiments, examples, etc. that are described herein. The above-described teachings, expressions, embodiments, examples, etc. should, therefore, not be viewed in isolation relative to each other. Various suitable ways in which the teachings herein may be combined will be readily apparent to those of ordinary skill in the art in view of the teachings herein. Such modifications and variations are intended to be included within the scope of protection provided by this document.

It should be appreciated that any patent, publication, or other disclosure material, in whole or in part, that is said to be incorporated by reference herein is incorporated herein only to the extent that the incorporated material does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

Having shown and described various versions of the inventors' technology, further adaptations of the methods and systems described herein may be accomplished by appropriate modifications by one of ordinary skill in the art without departing from the scope of the present invention. Several of such potential modifications have been mentioned, and others will be apparent to those skilled in the art. For instance, the examples, versions, geometries, materials, dimensions, ratios, steps, and the like discussed above are illustrative and are not required. Accordingly, the scope of protection provided by this document, or by other related documents should be considered in terms of the documents' claims and should not be limited to the details of structure and operation shown and described in the specification and drawings.

1. An optimization computing system, comprising a processor and a memory in communication with the processor, the memory storing programming instructions are executable by the processor to:
obtain a first data structure representing a plurality of chain tuples, each chain tuple characterizing a carbon causal chain that reflects a relationship between work, resources, and emissions;
obtain a second data structure representing a plurality of transition target tuples, each transition target tuple characterizing a possible shift between a current “business as usual” state and a “maximum transition” state;
identify, based on the second data structure, a weight for each of the plurality of transition target tuples; and
calculate an effect of each transition target tuple, as a function of the corresponding weight, on an aggregate of the chain tuples in the first data structure.

2. The optimization computing system of claim 1, wherein the programming instructions are further executable by the processor to produce output showing a composite effect of the plurality of transition target tuples.

3. The optimization computing system of claim 2, wherein:
each weight indicates a degree of the possible shift; and
the composite effect is a function of the weight for each of the plurality of the transition target tuples.

4. The optimization computing system of claim 1, wherein at least one of the plurality of transition target tuples characterizes a shift from use of a first type of device for achieving a result to using a second type of device for achieving the result.

5. The optimization computing system of claim 1, wherein at least one of the plurality of transition target tuples characterizes a shift from use of a first type of technology for achieving a result to using a second type of technology for achieving the result.

6. The optimization computing system of claim 1, further comprising a matrix data structure that includes:
first data tagging a first transition target tuple in the plurality of transition target tuples with a first time, and
second data tagging a second transition target tuple in the plurality of transition target tuples with the second time; and
wherein the programming instructions are further executable by the processor to account for implementation of the first transition target tuple at the first time and implementation of the second transition target tuple at the second time.

7. The optimization computing system of claim 1, further comprising a matrix data structure that includes:
first data tagging a first chain tuple in the plurality of chain tuples with a first time, and
second data tagging a second chain tuple in the plurality of chain tuples with the second time; and
wherein the programming instructions are further executable by the processor to account for effects of the first chain tuple at the first time and of the second chain tuple at the second time.

8. An optimization method, comprising the steps of:
obtaining, using a processor, a first data structure representing a plurality of chain tuples, each chain tuple characterizing a carbon causal chain that reflects a relationship between work, resources, and emissions;
obtaining, using the processor, a second data structure representing a plurality of transition target tuples, each transition target tuple characterizing a possible shift between a current “business as usual” state and a “maximum transition” state;
identifying, using the processor, a weight for each of a plurality of transition target tuples in the second data structure based on the possible shift; and
calculating, using the processor, an effect of each transition target tuple in the second data structure, as a function of the corresponding weight, on an aggregate of a plurality of chain tuples in the first data structure.

9. The optimization method of claim 8, wherein the programming instructions are further executable by the processor to produce output showing a composite effect of the plurality of transition target tuples.

10. The optimization method of claim 9, wherein:
each weight indicates a degree of the possible shift; and
the composite effect is a function of the weight for each of the plurality of the transition target tuples.

11. The optimization method of claim 8, wherein at least one of the plurality of transition target tuples characterizes a shift from use of a first type of device for achieving a result to using a second type of device for achieving the result.

12. The optimization method of claim 8, wherein at least one of the plurality of transition target tuples characterizes a shift from use of a first type of technology for achieving a result to using a second type of technology for achieving the result.

13. The optimization method of claim 8, further comprising a matrix data structure that includes:
first data tagging a first transition target tuple in the plurality of transition target tuples with a first time, and
second data tagging a second transition target tuple in the plurality of transition target tuples with the second time; and
wherein the programming instructions are further executable by the processor to account for implementation of the first transition target tuple at the first time and implementation of the second transition target tuple at the second time.

14. The optimization method of claim 8, further comprising a matrix data structure that includes:
first data tagging a first chain tuple in the plurality of chain tuples with a first time, and
second data tagging a second chain tuple in the plurality of chain tuples with the second time; and
wherein the programming instructions are further executable by the processor to account for effects of the first chain tuple at the first time and of the second chain tuple at the second time.

15. An optimization computing system, comprising a processor and a memory in communication with the processor, the memory storing programming instructions executable by the processor to:
obtain and store an initial plan data structure comprising an ambition data structure and a success probability data structure, wherein:
the ambition data structure comprises a plurality of ambition components, each ambition component comprising first transition target data, a goal metric, a baseline metric, and a measurability metric; whereby the first transition target data represent transitions of operations from one carbon causal chain (CCC) to another CCC, or changes in values for CCC parameters, and
the success probability data structure comprises a plurality of success probability components, each success probability component comprising second transition target data, buy-in data, and outcome data;
process the ambition data structure to produce an ambition score;
process the success probability data structure to produce a success probability score;
process the ambition score and the success probability score to produce a plan score; and
associate the plan score with the initial plan data structure.

16. The optimization computing system of claim 15, wherein: the memory also holds a plurality of additional plan data structures, and
the programming instructions are further executable by the processor to:
produce the plan score for each of the plurality of plan data structures; and
rank the initial plan data structure and the plurality of additional plan data structures according to the respective plan scores.

17. The optimization computing system of claim 16, wherein the programming instructions are further executable by the processor to iteratively:
identify a plurality of additional plan data structures as a function of the initial plan data structure,
process the additional plan data structures to produce a plan score for each of the additional plan data structures; and
choose one or more of the additional plan data structures for further processing;
until a final criterion is achieved, then: output one or more of the additional plan data structures.

18. The optimization computing system of claim 17, wherein:
at least one producing operation selected from the group consisting of
producing an ambition score,
producing a success probability score, and
producing a plan score
comprises simulating, as a plurality of agents, where each of the plurality of agents has a state, at least one of:
the transitions of operations from one CCC to another CCC; or
changes in values for CCC parameters; or
activities that form the subject of at least one of the initial plan data structure or one of the additional plan data structures, and
the iteration comprises selecting a strategy for each particular one of the plurality of agents from a plurality of strategies, wherein said selecting:
operates as a function of the state of the particular one of the plurality of agents and the state of one or more other agents in the plurality of agents; and
changes simulated behavior of the agent to maximize economic benefit, support a necessary level of activity, and reduce carbon output.

19. An optimization method, comprising the steps of:
obtaining, using a processor, an initial plan data structure comprising an ambition data structure and a success probability data structure, and
storing the initial plan data structure, wherein:
the ambition data structure comprises a plurality of ambition components, each ambition component comprising first transition target data, a goal metric, a baseline metric, and a measurability metric, whereby the first transition target data represent at least one of
transitions of operations from one carbon causal chain (CCC) to another CCC or
changes in values for CCC parameters; and
the success probability data structure comprises a plurality of success probability components, each success probability component comprising second transition target data, buy-in data, and outcome data;
processing, using the processor, the ambition data structure to produce an ambition score;
processing, using the processor, the success probability data structure to produce a success probability score;
processing, using the processor, the ambition score and the success probability score to produce a plan score; and
associating, using the processor, the plan score with the initial plan data structure.

20. The optimization method of claim 19, further comprising:
storing a plurality of additional plan data structures;
producing the plan score for each of the plurality of plan data structures; and
ranking the initial plan data structure and the plurality of additional plan data structures according to the respective plan scores.

21. The optimization method of claim 20, further comprising iteratively:
identifying a plurality of additional plan data structures as a function of the initial plan data structure,
processing the additional plan data structures to produce a plan score for each of the additional plan data structures; and
choosing one or more of the additional plan data structures for further processing;
until a final criterion is achieved, then: outputting one or more of the additional plan data structures.

22. The optimization method of claim 21, wherein:
at least one processing step selected from the group consisting of
processing an ambition score,
processing a success probability score, and
processing a plan score
comprises simulating as a plurality of agents, where each of the plurality of agents has a state, at least one of
the transitions of operations from one CCC to another CCC, or
changes in values for CCC parameters, or
activities that form the subject of at least one of the initial plan data structure or one of the additional plan data structures, and
the iteration comprises selecting a strategy for each particular one of the plurality of agents from a plurality of strategies, wherein said selecting:
operates as a function of the state of the particular one of the plurality of agents and the state of one or more other agents in the plurality of agents; and
changes simulated behavior of the agent to maximize economic benefit, support a necessary level of activity, and reduce carbon output.

23. The optimization computing system of claim 17, wherein:
at least one producing operation selected from the group consisting of
producing an ambition score,
producing a success probability score, and
producing a plan score
comprises simulating as a plurality of agents, each of the plurality of agents having a state, at least one of:
transition targets; or
activities that form the subject of at least one of the initial plan data structure or one of the additional plan data structures, and
the iteration comprises selecting a strategy for each particular one of the plurality of agents from a plurality of strategies, wherein said selecting:
operates as a function of the state of the particular one of the plurality of agents and the state of one or more other agents in the plurality of agents; and
changes simulated behavior of the agent to maximize economic benefit, support a necessary level of activity, and reduce carbon output.
